(19) United States
(12) Patent Application Publication
(10) Pub. No.: US 2007/0070600 A1
(43) Pub. Date: Mar. 29, 2007

(54) Electronic apparatus

(76) Inventors: Kentaro Tomioka, Sayama-shi (JP); Hiroshi Nishibayashi, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/528,961

(22) Filed: Sep. 27, 2006

(30) Foreign Application Priority Data
Sep. 28, 2005 (JP) P2005-281716

(51) Int. Cl. H05K 7/20; F28F 7/00

(52) U.S. Cl. 361/688; 165/80.3

(57) ABSTRACT

According to one embodiment, an electronic apparatus comprising a housing including a suction port and an exhaust port, a heat generating element accommodated in the housing, a heat receiving portion accommodated in the housing, and thermally connected to the heat generating element, a fan disposed in the vicinity of the suction port within the housing, and which sucks a cooling air through the suction port, and a heat radiating portion accommodated in the housing, and configured to radiate heat of the heat generating element, wherein the heat radiating portion is disposed between the suction port and the fan, and the heat receiving portion is arranged in a discharge region of the cooling air extending from the fan to the exhaust port.

### CROSS-REFERENCE TO RELATED APPLICATIONS

This application is based upon and claims the benefit of priority from Japanese Patent Application No. 2005-281716, filed Sep. 28, 2005, the entire contents of which are incorporated herein by reference.

### BACKGROUND

1. Field

One embodiment of the invention relates to an electronic apparatus in which an electronic component generating heat, for example, a CPU is installed, and more particularly to a structure for heightening the cooling efficiency of the electronic component.

2. Description of the Related Art

An electronic component such as CPU or VGA controller, for use in an electronic apparatus, tends to rapidly increase in the quantity of heat generation in consequence of high-density packaging and functional enhancements. When the temperature of the electronic component becomes excessively high, there occurs the drawback that the efficient operation of the electronic component is lost, or that the electronic component becomes inoperative.

As a thermal countermeasure against the drawback, in a prior-art electronic apparatus, suction ports and exhaust ports are formed in a housing which serves as the outer frame of the electronic apparatus, and a cooling device which forcibly cools the electronic component is accommodated in the housing. The cooling device includes a heat receiving portion which receives the heat of the electronic component, a heat radiating portion which radiates the heat of the electronic component, heat transfer means for transferring to the heat radiating portion, the heat of the electronic component as has been transmitted to the heat receiving portion, and a fan which blows cooling air to the heat radiating portion.

In the prior-art electronic apparatus, the heat radiating portion and the fan are disposed in the housing so as to adjoin the exhaust ports. The fan sucks air within the housing, and blows the air against the heat radiating portion. The air blown against the heat radiating portion is warmed by heat exchange with the heat radiating portion, and is discharged out of the housing through the exhaust ports.

However, circuit components and a drive unit which generate heats during operations exist in the housing, so that the temperature of the air within the housing has already risen under the thermal influences of the circuit components and the drive unit. In consequence, the fan sucks the warm air within the housing and blows the air against the heat radiating portion, and the temperature difference between the air and the heat radiating portion becomes small. Therefore, the heat radiating portion cannot be efficiently cooled.

As a measure for improving the situation, an electronic apparatus wherein the fan and the heat radiating portion are arranged in the vicinity of the suction ports of the housing has been proposed (Refer to JP-A-8-162576). According to this electronic apparatus, the fan sucks cool air outside the housing and blows the air against the heat radiating portion, so that the heat radiating portion can be efficiently cooled.

In the electronic apparatus disclosed in JP-A-8-162576, the fan is arranged upstream of the heat radiating portion along the blowing direction of the air, and the vane wheel of the fan confronts the suction ports. In other words, the heat radiating portion lies on the deeper side of the housing with respect to the fan, so that radiant heat from the heat radiating portion is liable to stagnate within the housing. Accordingly, the ambient temperature of the heat radiating portion becomes high, and such an arrangement is disadvantageous for heightening the cooling efficiency of the heat radiating portion.

In addition, the vane wheel of the fan is seen through the suction ports, and hence, especially when the fan is rotated at high speed, the running sound of the fan directly comes out of the housing from the suction ports. As a result, the running sound of the fan becomes noise to unfavorably form a cause for an offensive feeling.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of an electronic apparatus according to the first embodiment of the present invention;

FIG. 2 is an exemplary sectional view of the electronic apparatus according to the first embodiment of the invention;

FIG. 3 is an exemplary sectional view of a first heat-receiving portion which is thermally connected to a first heat-generating element, in the first embodiment of the invention;

FIG. 4 is an exemplary sectional view showing a state where a heat exchange type pump and a second heat-generating element are thermally connected, in the first embodiment of the invention;

FIG. 5 is an exemplary perspective view of the heat exchange type pump showing a state where a casing body and a heat receiving cover are separated from each other, in the first embodiment of the invention;

FIG. 6 is an exemplary plan view of the casing body showing a state where a vane wheel is accommodated in a pump chamber, in the first embodiment of the invention;

FIG. 7 is an exemplary perspective view of the casing body according to the first embodiment of the invention;

FIG. 8 is an exemplary front view of a radiator which is employed in the first embodiment of the invention;

FIG. 9 is an exemplary sectional view of the radiator showing the positional relationship between a radiator core and a reserve tank, in the first embodiment of the invention;

FIG. 10 is an exemplary front view of an auxiliary cooling device which projects from a printed-wiring circuit board into a discharge region, in the first embodiment of the invention;

FIG. 11 is an exemplary sectional view of a radiator showing the positional relationship between a radiator core and a reserve tank, in the second embodiment of the invention;

FIG. 12 is an exemplary perspective view of an electronic apparatus according to the third embodiment of the invention;

FIG. 13 is an exemplary sectional view of the electronic apparatus according to the third embodiment of the invention;

FIG. 14 is an exemplary front view showing the positional relationship between two radiators, in the third embodiment of the invention;

FIG. 15 is an exemplary sectional view of an electronic apparatus according to the fourth embodiment of the invention;

FIG. 16 is an exemplary front view of a heat radiating unit according to the fourth embodiment of the invention; and

FIG. 17 is an exemplary sectional view of an electronic apparatus according to the fifth embodiment of the invention.

### DETAILED DESCRIPTION

Various embodiments according to the invention will be described hereinafter with reference to the accompanying drawings. In general, according to one embodiment of the invention, an electronic apparatus comprising a housing including a suction port and an exhaust port, a heat generating element accommodated in the housing, a heat receiving portion accommodated in the housing, and thermally connected to the heat generating element, a fan disposed in the vicinity of the suction port within the housing, and which sucks a cooling air through the suction port, and a heat radiating portion accommodated in the housing, and configured to radiate heat of the heat generating element, wherein the heat radiating portion is disposed between the suction port and the fan, and the heat receiving portion is arranged in a discharge region of the cooling air extending from the fan to the exhaust port.

In order to accomplish the object, an electronic apparatus according to one aspect of the present invention comprises a housing which has suction ports and exhaust ports, a heat generating element which is accommodated in the housing, a heat receiving portion which is accommodated in the housing, and which is thermally connected to the heat generating element, a fan which is arranged in the vicinity of the suction ports within the housing, and which sucks cooling air through the suction ports, and a heat radiating portion which is accommodated in the housing, and which radiates heat of the heat generating element. Here, the heat radiating portion is arranged between the suction ports and the fan, and the heat receiving portion is arranged in a discharge region of the cooling air as extends from the fan to the exhaust ports.

According to the present invention, a temperature rise within the housing can be prevented while the heat radiating portion is being efficiently cooled by air outside the housing. Moreover, the suction ports are covered with the heat radiating portion from inside of the housing, so that the running sound of the fan can be intercepted by the heat radiating portion.

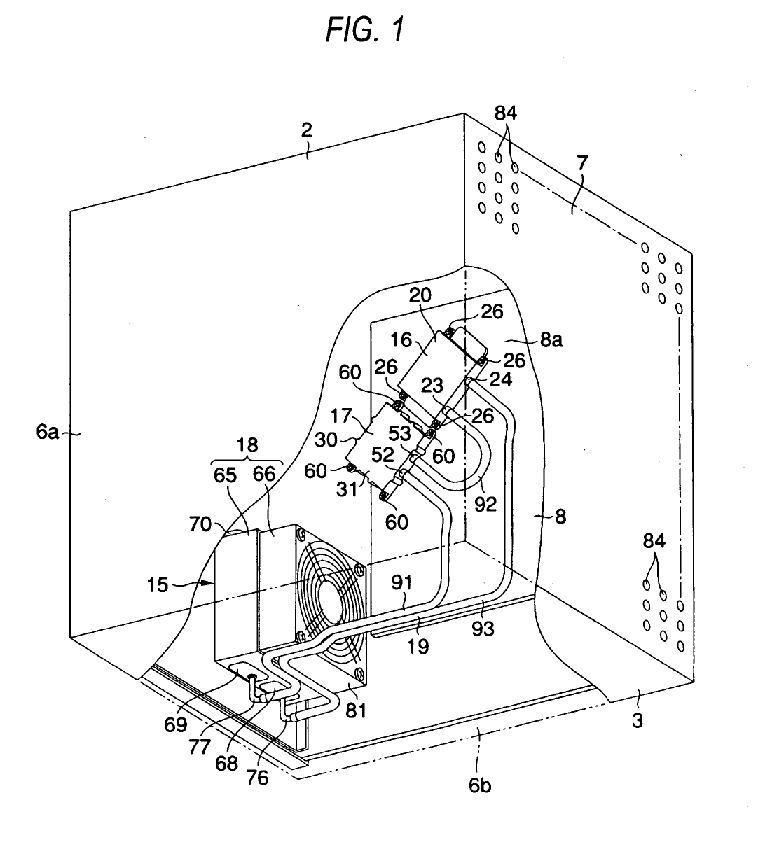

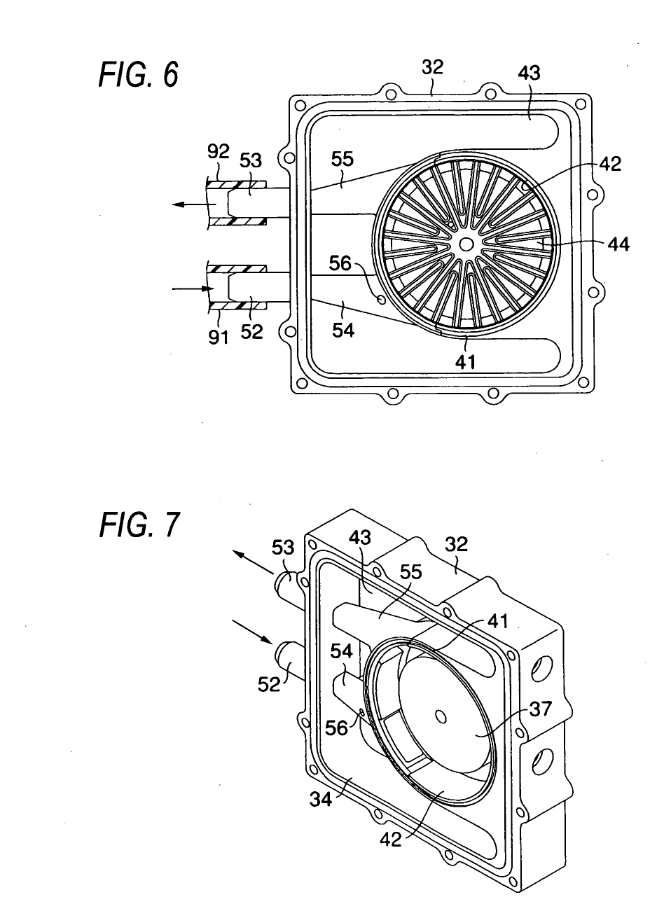

The first embodiment of the present invention will be described with reference to FIGS. 1 through 10.

FIG. 1 shows a stationary type computer 1 which is an example of an electronic apparatus. The computer 1 includes a housing 2 which is put on, for example, the top of a desk. The housing 2 is in the shape of an empty box which includes a bottom wall 3, a top wall 4, a front wall 5, left and right sidewalls 6a and 6b, and a rear wall 7.

The housing 2 accommodates a printed circuit board 8 therein. The printed circuit board 8 stands upright along the depth direction of the housing 2 in parallel with the sidewalls 6a and 6b.

The printed circuit board 8 includes a first surface 8a, and a second surface 8b which lies on a side opposite to the first surface 8a. A first heat-generating element 10 and a second heat-generating element 11 are mounted on the first surface 8a of the printed circuit board 8.

The first heat-generating element 10 is a semiconductor package which constructs, for example, a VGA controller. The second heat-generating element 11 is a BGA type semiconductor package which constructs, for example, a CPU. The first and second heat-generating elements 10, 11 adjoin each other at the middle part of the printed circuit board 8.

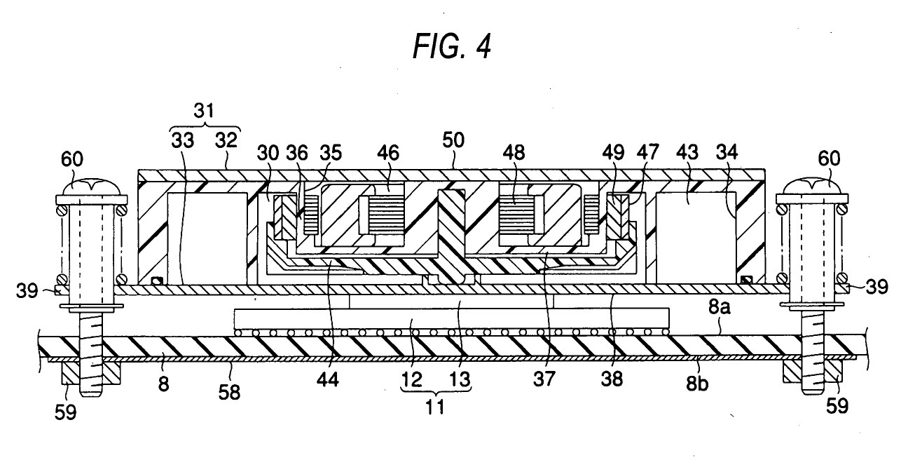

As shown in FIG. 4, the second heat-generating element 11 includes a base substrate 12 and an IC chip 13. The base substrate 12 is soldered onto the first surface 8a of the printed circuit board 8. The IC chip 13 is mounted on the middle part of the base substrate 12. The second heat-generating element 11 is larger than the first heat-generating element 10 in the quantity of heat generation during operation, in consequence of the heightened processing speed and multifunctionalization of the IC chip 13. Both the first and second heat-generating elements 10, 11 require cooling in order to keep stable operations.

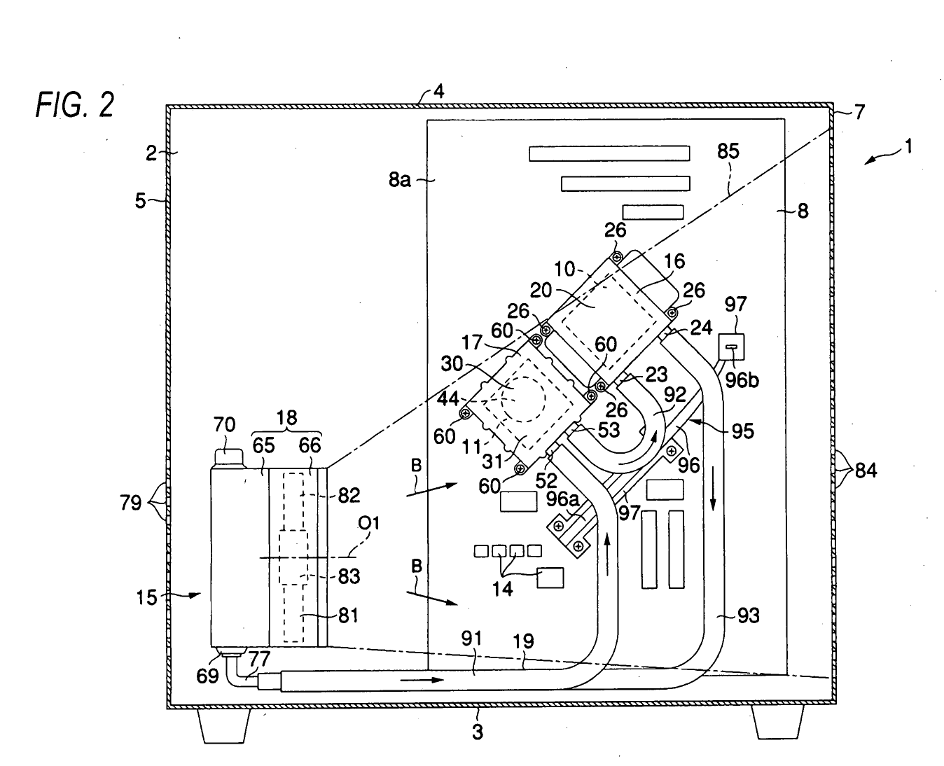

As shown in FIG. 2, a plurality of electronic components 14 being other heat-generating elements are mounted on the first surface 8a and second surface 8b of the printed circuit board 8. The electronic components 14 lie below the first and second heat-generating elements 10, 11, and they are smaller than the first and second heat-generating elements 10, 11 in the quantity of heat generation during operation.

As shown in FIGS. 1 and 2, the housing 2 of the computer 1 is furnished with a cooling device 15 of liquid cooling scheme as cools the first and second heat-generating elements 10, 11 by using a liquid coolant, for example, water or an antifreezing solution. The cooling device 15 includes a first heat-receiving portion 16, a second heat-receiving portion 17, a heat radiating unit 18 and a circulation path 19.

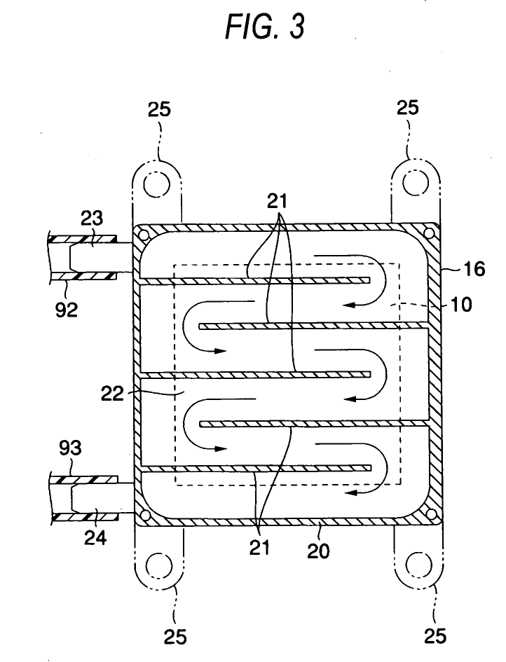

As shown in FIG. 3, the first heat-receiving portion 16 includes a heat receiving casing 20. The heat receiving casing 20 is in the shape of a flat square box which is somewhat larger than the first heat-generating element 10, and which is made of a metal material of high thermal conductivity, for example, an aluminum alloy.

A plurality of guide walls 21 are formed within the heat receiving casing 20. The guide walls 21 define a coolant passage 22 through which the liquid coolant flows, within the heat receiving casing 20. The coolant passage 22 is bent zigzag.

The heat receiving casing 20 includes an inflow port 23 which lies at the upstream end of the coolant passage 22, and an outflow port 24 which lies at the downstream end of the coolant passage 22. The inflow port 23 and the outflow port 24 protrude unidirectionally from the side surface of the heat receiving casing 20.

Further, the heat receiving casing 20 includes four tongue pieces 25. The tongue pieces 25 project around the heat receiving casing 20 from the four corners of this heat receiving casing 20, and they are respectively fixed to the printed circuit board 8 through screws 26. Thus, the heat receiving casing 20 is held on the printed circuit board 8 and is thermally connected to the first heat-generating element 10 at an attitude at which it covers this first heat-generating element 10.

As shown in FIGS. 4 through 7, the second heat-receiving portion 17 is a separate constituent which is independent of the first heat-receiving portion 16, and in which a heat exchange type pump 30 is built. The heat exchange type pump 30 includes a pump casing 31 which serves also as a heat receiving casing.

The pump casing 31 includes a casing body 32 and a heat receiving cover 33. The casing body 32 is in the shape of a flat square box which is somewhat larger than the second heat-generating element 11, and it is made of, for example, a synthetic resin material which has a heat resisting property.

The casing body 32 includes a first recess 34 and a second recess 35. The first recess 34 and the second recess 35 are open in senses reverse to each other so as to extend in the thickness direction of the casing body 32. The second recess 35 includes a cylindrical peripheral wall 36, and a circular end wall 37 which lies at one end of the peripheral wall 36. The peripheral wall 36 and the end wall 37 lie inside of the first recess 34.

The heat receiving cover 33 is made of a metal material of high thermal conductivity, for example, copper or aluminum. Besides, the heat receiving cover 33 is fixed to the casing body 32 so as to close the open end of the first recess 34. Further, the heat receiving cover 33 includes a flat heat-receiving surface 38 which is exposed out of the pump casing 31. Tongue pieces 39 are respectively formed at the four corners of the heat receiving cover 33. The tongue pieces 39 project around the casing body 32.

As shown in FIGS. 4 and 7, the casing body 32 includes a cylindrical peripheral wall 41. The peripheral wall 41 surrounds the peripheral wall 36 of the second recess 35 coaxially, and the lower end thereof is bonded to the heat receiving cover 33. Besides, the peripheral wall 41 partitions the interior of the first recess 34 into a pump chamber 42 and a reserve tank 43.

A vane wheel 44 is accommodated in the pump chamber 42. The vane wheel 44 is rotatably supported between the end wall 37 of the second recess 35 and the heat receiving cover 33 of the pump casing 31. The reserve tank 43 serves to store the liquid coolant, and it surrounds the pump chamber 42.

A flat motor 46 for rotating the vane wheel 44 is assembled in the casing body 32. The flat motor 46 includes a rotor 47 and a stator 48. The rotor 47 is coaxially fixed to the outer peripheral part of the vane wheel 44, and it lies at the outer peripheral part of the pump chamber 42. A magnet 49 is fitted inside of the rotor 47. The magnet 49 is rotated integrally with the rotor 47 and the vane wheel 44.

The stator 48 is accommodated in the second recess 35 of the casing body 32. Besides, the stator 48 is coaxially located inside of the magnet 49 of the rotor 47. The peripheral wall 36 of the second recess 35 is interposed between the stator 48 and the magnet 49. The open end of the second recess 35 is closed by a backplate 50 which covers the stator 48.

The stator 48 is energized simultaneously with the turn-ON of the power source of the computer 1 by way of example. Owing to the energization, a rotating magnetic field is generated in the circumferential direction of the stator 48, and the magnetic field is magnetically coupled with the magnet 49 of the rotor 47. As a result, a torque which extends along the circumferential direction of the rotor 47 is generated between the stator 48 and the magnet 49, and the vane wheel 44 is rotated.

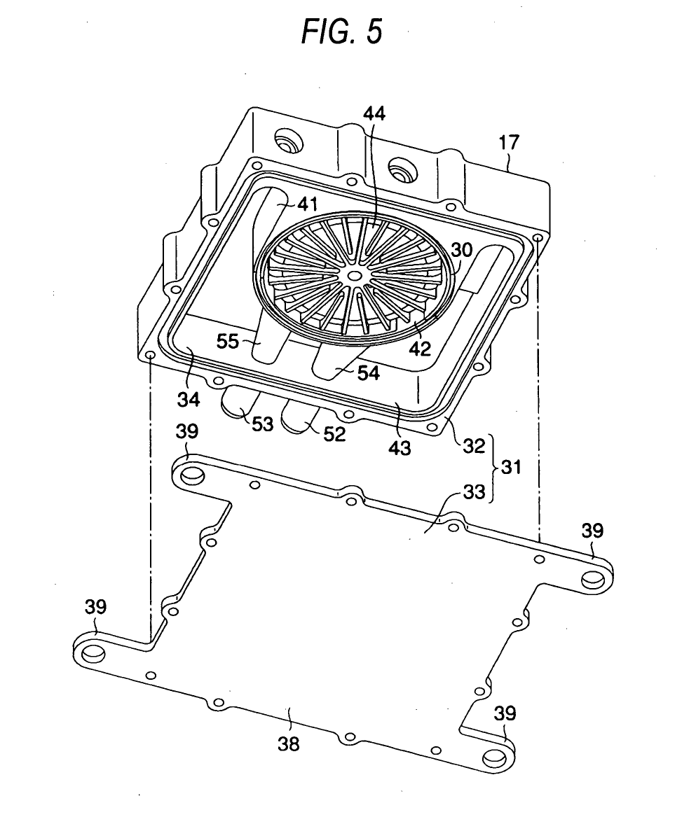

As shown in FIGS. 5 through 7, the casing body 32 includes a suction port 52 for sucking the liquid coolant, and a discharge port 53 for discharging the liquid coolant. The suction port 52 and the discharge port 53 protrude unidirectionally from the side surface of the casing body 32.

The suction port 52 communicates with the pump chamber 42 through a first connection passage 54. The discharge port 53 communicates with the pump chamber 42 through a second connection passage 55. The first and second connection passages 54, 55 traverse the interior of the reserve tank 43. The first connection passage 54 includes a through-hole 56 for gas-liquid separation. The through-hole 56 is open to the interior of the reserve tank 43, and it always lies below the liquid level of the liquid coolant stored in the reserve tank 43.

As shown in FIG. 4, the second heat-receiving portion 17 is attached to the printed circuit board 8 at an attitude at which the heat receiving cover 33 of the heat exchange type pump 30 faces the second heat-generating element 11. A metallic reinforcement plate 58 is stacked on the second surface 8b of the printed circuit board 8. The reinforcement plate 58 confronts the heat exchange type pump 30 with the printed circuit board 8 interposed therebetween, and it includes nuts 59 at positions corresponding to the four tongue pieces 39 of the pump casing 31.

Screws 60 are inserted through the tongue pieces 39 of the pump casing 31. The screws 60 are threadably engaged with the nuts 59 while penetrating through the printed circuit board 8. Owing to the threadable engagements, the second heat-receiving portion 17 which is integral with the heat exchange type pump 30 is held on the printed circuit board 8 at an attitude at which it covers the second heat-generating element 11. As a result, the heat receiving surface 38 of the heat receiving cover 33 is thermally connected to the IC chip 13 of the second heat-generating element 11.

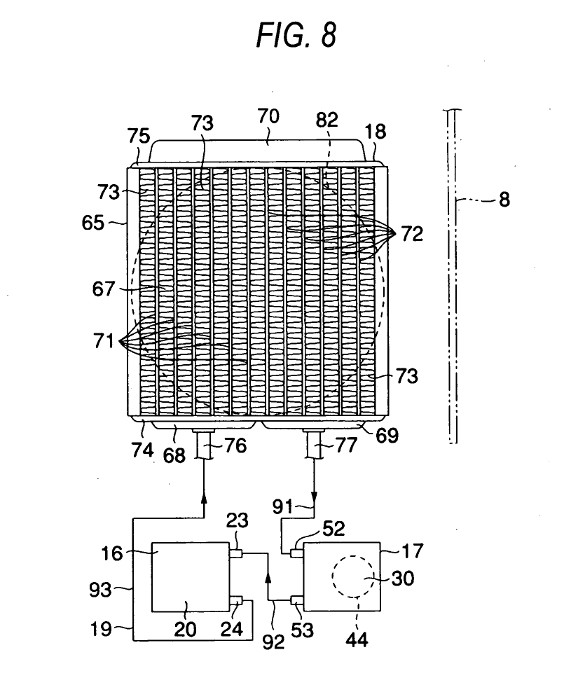

As shown in FIGS. 1 and 2, the heat radiating unit 18 of the cooling device 15 is disposed at the lower part of the front end of the housing 2. The heat radiating unit 18 serves to radiate the heats of the first and second heat-generating elements 10, 11, and it includes a radiator 65 being a heat radiation portion, and an axial fan 66. As shown in FIG. 8, the radiator 65 includes a radiator core 67, an inflow tank 68, an outflow tank 69 and a reserve tank 70.

The radiator core 67 includes a plurality of first water pipes 71 through which the liquid coolant flows, a plurality of second water pipes 72 through which the liquid coolant flows, and a plurality of fins 73. The first and second water pipes 71, 72 form in line with intervals between the adjacent ones of them, and they stand upright along the height direction of the housing 2. The fins 73 are interposed between the adjacent ones of the water pipes 71, 72, and they are thermally connected to the water pipes 71, 72. The lower ends of the first and second water pipes 71, 72 are coupled by a lower plate 74. Likewise, the upper ends of the first and second water pipes 71, 72 are coupled by an upper plate 75.

The inflow tank 68 and the outflow tank 69 are respectively brazed onto the lower surface of the lower plate 74, and they are juxtaposed in the array direction of the first and second water pipes 71, 72. The inflow tank 68 has a size corresponding to the array region of the first water pipes 71, and a coolant inlet 76 is formed at the middle part of the inflow tank 68. The lower ends of the first water pipes 71 are open into the inflow tank 68.

The outflow tank 69 has a size corresponding to the array region of the second water pipes 72, and a coolant outlet 77 is formed at the middle part of the outflow tank 69. The lower ends of the second water pipes 72 are open into the outflow tank 69.

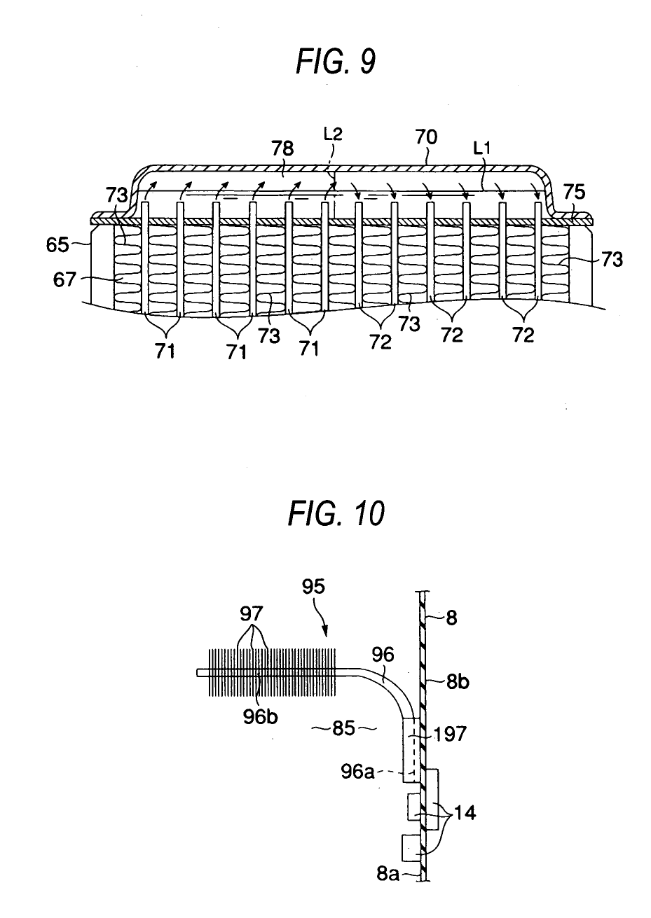

As shown in FIG. 9, the reserve tank 70 is brazed onto the upper surface of the upper plate 75. Besides, the reserve tank 70 has a size spreading over the array regions of the first and second water pipes 71, 72, and it extends along the width direction of the radiator core 67. The upper ends of the first water pipes 71 and those of the second water pipes 72 are open into the reserve tank 70.

The liquid coolant is introduced from the coolant inlet 76 into the inflow tank 68, and it flows into the lower ends of the first water pipes 71. After the liquid coolant has flowed through the first water pipes 71 upwards from below, it is discharged into the reserve tank 70. The liquid coolant discharged into the reserve tank 70 is temporarily stored in this reserve tank 70, and it flows into the upper ends of the second water pipes 72. After the liquid coolant has flowed through the second water pipes 72 downwards from above, it is discharged into the outflow tank 69.

As shown in FIG. 9, the upper ends of the first and second water pipes 71, 72 lie below the liquid level L1 of the liquid coolant stored in the reserve tank 70. An air pocket 78 is formed between the upper surface of the reserve tank 70 and the liquid level L1 of the liquid coolant.

Therefore, in a case where gas components, for example, air bubbles are contained in the liquid coolant which is discharged from the first water tubes 71 into the reserve tank 70, the gas components are separated from the liquid coolant and emitted into the air pocket 78 in a process before the liquid coolant flows into the second water pipes 72.

Accordingly, the reserve tank 70 in this embodiment serves also as a gas-liquid separation section which separates the gas components from the liquid coolant introduced into the radiator 65.

By the way, in some layouts of the interior of the housing 2, the radiator 65 can be disposed at a horizontal attitude at which the first and second water pipes 71, 72 become horizontal. In this case, the sense of the radiator 65 is stipulated so that the second water pipes 72 may underlie the first water pipes 71. Thus, those end parts of the second water pipes 72 which are open into the reserve tank 70 lie below the liquid level L2 of the liquid coolant as indicated by a two-dot chain line in FIG. 9.

Therefore, even when air bubbles are contained in the liquid coolant which is discharged from the first water pipes 71 into the reserve tank 70, the air bubbles are separated from the liquid coolant within the reserve tank 70.

The radiator 65 of such a configuration stands upright so as to extend along the front wall 5 of the housing 2, and it is located in the vicinity of a plurality of suction ports 79 provided in the front wall 5. In other words, the radiator 65 confronts the suction ports 79, and it covers these suction ports 79 from inside of the housing 2.

The axial fan 66 of the heat radiating unit 18 includes a square fan case 81, a vane wheel 82 which is accommodated in the fan case 81, and a motor 83 which rotates the vane wheel 82. The vane wheel 82 is supported by the fan case 81 at a horizontal attitude at which the axis of rotation O1 of this vane wheel extends along the depth direction of the housing 2.

The axial fan 66 is disposed behind the radiator 65, and it lies on the inner side of the housing 2 with respect to the radiator 65. In other words, the radiator 65 is arranged between the suction ports 79 and the axial fan 66. Thus, the vane wheel 82 of the axial fan 66 confronts the suction ports 79 with the radiator 65 interposed therebetween.

When the vane wheel 82 is rotated, a negative pressure acts on the suction ports 79 of the housing 2, and air outside the housing 2 is sucked into the suction ports 79. The sucked air becomes cooling air and passes through the radiator core 67, and it is discharged from the fan case 81 to the inner part of the housing 2. The cooling air warmed by heat exchange with the radiator core 67 passes around the printed circuit board 8 and the first and second heat-receiving portions 16, 17 until it arrives at the rear end of the housing 2. The cooling air is exhausted out of the housing 2 through a plurality of exhaust ports 84 which are provided in the rear wall 7 of the housing 2.

As indicated by arrows B in FIG. 2, the cooling air discharged from the axial fan 66 flows through a discharge region 85 within the housing 2. The discharge region 85 is defined between the discharge end of the axial fan 66 and the rear wall 7 of the housing 2, and the exhaust ports 84 lie at the downstream end of the discharge region 85.

According to this embodiment, the exhaust ports 84 are formed so as to disperse over substantially the whole area of the rear wall 7. Therefore, the discharge region 85 flares in the height direction of the housing 2 gradually from the axial fan 66 toward the exhaust ports 84. The first and second heat-generating elements 10, 11, the first and second heat-receiving elements 16, 17, and the electronic components 14 involving the heat generations during their operations are located in the discharge region 85, and they are directly exposed to the cooling air flowing through the discharge region 85.

As shown in FIGS. 1 and 2, the circulation path 19 of the cooling device 15 serves to circulate the liquid coolant, and it serially connects the first heat-receiving portion 16, second heat-receiving portion 17 and radiator 65.

The circulation path 19 includes first through third tubes 91, 92, 93. The first through third tubes 91, 92, 93 are made of a flexible material, for example, a rubber or synthetic resin.

The first tube 91 connects the coolant outlet 77 of the radiator 65 and the suction port 52 of the heat exchange type pump 30. The second tube 92 connects the discharge port 53 of the heat exchange type pump 30 and the inflow port 23 of the first heat-receiving portion 16. The third tube 93 connects the outflow port 24 of the first heat-receiving portion 16 and the coolant inlet 76 of the radiator 65.

The liquid coolant flowing out from the coolant outlet 77 of the radiator 65 is led to the first heat-receiving portion 16 via the second heat-receiving portion 17, and it is thereafter returned to the coolant inlet 76 of the radiator 65. Therefore, the second heat-receiving portion 17 lies upstream of the first heat-receiving portion 16 along the flow direction of the liquid coolant, and it lies downstream of the radiator 65 along the flow direction of the liquid coolant.

As shown in FIGS. 2 and 10, an auxiliary cooling device 95 is mounted on the first surface 8a of the printed circuit board 8. The auxiliary cooling device 95 serves to promote the heat radiations of the printed circuit board 8 and electronic components 14, and it includes a heat pipe 96 and a plurality of heat radiating fins 97.

The heat pipe 96 has a heat receiving end part 96a and a heat radiating end part 96b, and it is bent substantially at right angles so that both the end parts 96a, 96b may fall into a positional relationship orthogonal to each other. The heat receiving end part 96a of the heat pipe 96 is thermally connected to the first surface 8a of the printed circuit board 8 through a heat pipe holder 197. The thermal connection part between the heat receiving end part 96a and the printed circuit board 8 lies in the vicinity of the electronic components 14. The heat radiating end part 96b of the heat pipe 96 protrudes from the first surface 8a of the printed circuit board 8 toward the sidewall 6a of the housing 2, and it projects into the discharge region 85.

The heat radiating fins 97 are thermally connected to the heat radiating end part 96b of the heat pipe 96. Besides, the heat radiating fins 97 are juxtaposed with intervals in the axial direction of the heat radiating end part 96b, and they are exposed to the discharge region 85.

When the electronic components 14 generate heats, their heats are transmitted to the printed circuit board 8. Thus, the printed circuit board 8 becomes a high temperature locally, and its heat is transmitted to the heat receiving end part 96a of the heat pipe 96. Owing to the heat transmission, a working solution enclosed in the heat receiving end part 96a is overheated to turn into a vapor. The vapor flows from the heat receiving end part 96a toward the heat radiating end part 96b, and is condensed in this heat radiating end part 96b. Heat radiated by the condensation is transmitted to the heat radiating fins 97, and it is radiated while being carried on the streams of cooling air which flows through the discharge region 85 from the surfaces of the heat radiating fins 97.

The working solution liquefied at the heat radiating end part 96b returns to the heat receiving end part 96a under a capillary action, and it receives the heat of the printed circuit board 8 again. Owing to the repetition of the vaporization and condensation of the working solution, the heats of the electronic components 14 as are transmitted to the printed circuit board 8 are transferred to the heat radiating fins 97.

Such an auxiliary cooling device 95 is additionally mounted on the printed circuit board 8, whereby the heats of the electronic components 14 as are transmitted to the printed circuit board 8 can be transferred to the discharge region 85 and be positively radiated therefrom. Accordingly, the heat radiating performances of the electronic components 14 are enhanced, and the local overheat of the printed circuit board 8 can be avoided.

Next, the operation of the cooling device 15 will be described.

During the use of the computer 1, the first heat-generating element 10 and the second heat-generating element 11 generate heats. The heat generated by the first heat-generating element 10 is transmitted to the heat receiving casing 20 of the first heat-receiving portion 16. Since the coolant passage 22 in the heat receiving casing 20 is filled up with the liquid coolant, this liquid coolant absorbs the heat of the first heat-generating element 10 as is transmitted to the heat receiving casing 20.

On the other hand, the heat generated by the second heat-generating element 11 is transmitted to the pump casing 31 of the heat exchange type pump 30 through the heat receiving surface 38. Since the pump chamber 42 and reserve tank 43 in the pump casing 31 are filled up with the liquid coolant, this liquid coolant absorbs the heat of the second heat-generating element 11 as is transmitted to the pump casing 31.

When the vane wheel 44 of the heat exchange type pump 30 rotates, the liquid coolant packed in the pump chamber 42 is endowed with kinetic energy, and the pressure of the liquid coolant in the pump chamber 42 is raised by the kinetic energy. The pressurized liquid coolant is pushed out from the pump chamber 42 to the discharge port 53 through the second connection passage 55.

In other words, the liquid coolant in the pump chamber 42 is pressurized by the rotating vane wheel 44 while depriving the second heat-generating element 11 of its heat. Therefore, the flow velocity of the liquid coolant flowing through the pump chamber 42 is heightened, and heat transmission from the pump casing 31 to the liquid coolant proceeds efficiently.

The liquid coolant pressurized in the pump chamber 42 flows from the discharge port 53 into the coolant passage 22 of the first heat-receiving portion 16 through the second tube 92. The liquid coolant absorbs the heat of the first heat-generating element 10 as is transmitted to the heat receiving casing 20, in a process in which it flows through the coolant passage 22.

At the point of time at which the liquid coolant flows into the coolant passage 22 of the first heat-receiving portion 16, the temperature of the liquid coolant is high on account of a heat receiving action in the second heat-receiving portion 17. In this embodiment, however, the flow rate of the liquid coolant per unit time is determined so that the temperature of the liquid coolant which is led to the first heat-receiving portion 16 may become lower than the temperature of the first heat-generating element 10 as is transmitted to the heat receiving casing 20.

As a result, the temperature difference between the liquid coolant and the heat receiving casing 20 is ensured, and when the liquid coolant flows through the coolant passage 22, the heat of the first heat-generating element 10 as is transmitted to the heat receiving casing 20 can be deprived of by the liquid coolant.

The liquid coolant having passed through the coolant passage 22 is fed from the outflow port 24 into the inflow tank 68 of the radiator 65 through the third tube 93. The liquid coolant returned into the inflow tank 68 is introduced into the reserve tank 70 through the first water pipes 71, and it is fed from this reserve tank into the outflow tank 69 through the second water pipes 72. In the process of the flow, the heats of the first and second heat-generating elements 10, 11 as have been absorbed in the liquid coolant are transmitted to the first and second water pipes 71, 72 and the fins 73.

The axial fan 66 of the heat radiating unit 18 starts running when, by way of example, the temperature of the liquid coolant has reached a predetermined value. Thus, the vane wheel 82 is rotated, and the air outside the housing 2 is sucked into the housing 2 through the suction ports 79. The air becomes the cooling air and passes through the spaces between the first and second water pipes 71, 72, thereby to forcibly cool the first and second water pipes 71, 72 and the fins 73. As a result, most of the heats transmitted to the first and second water pipes 71, 72 and the fins 73 is carried away on the streams of the cooling air.

The liquid coolant cooled by the heat exchange in the radiator 65 is introduced from the outflow tank 69 into the pump chamber 42 of the heat exchange type pump 30 through the first tube 91. This liquid coolant is pressurized by the rotation of the vane wheel 44 while depriving the pump casing 31 of its heat, and it is fed out toward the coolant passage 22 of the first heat-receiving portion 16.

Therefore, the liquid coolant is repeatedly circulated among the radiator 65, second heat-receiving portion 17 and first heat-receiving portion 16, and the heats of the first and second heat-generating elements 10, 11 are transferred to the radiator 65 by the circulation.

According to such first embodiment, the radiator 65 can be directly cooled by the air outside the housing 2, and the cooling efficiency of the radiator 65 is enhanced.

Simultaneously, the radiator 65 receiving the heat of the liquid coolant is exposed to the exterior of the housing 2 through the suction ports 79, and hence, part of radiant heat from the radiator 65 can be directly radiated out of the housing 2 through the suction ports 79. Therefore, the heat of the radiator 65 is less liable to stagnate within the housing 2, and the ambient temperature of the radiator 65 is suppressed to be low, so that the cooling performance of the radiator 65 can be heightened.

Moreover, the cooling air which is discharged from the axial fan 66 after having cooled the radiator 65 passes through the discharge region 85 within the housing 2 and is exhausted out of the housing 2 through the exhaust ports 84. Therefore, an air permeability in the housing 2 becomes favorable. In particular, the first and second heat-generating elements 10, 11 and the first and second heat-receiving portions 16, 17 lie in the discharge region 85 within the housing 2, and hence, the first and second heat-generating elements 10, 11 and the first and second heat-receiving portions 16, 17 can be cooled by utilizing the cooling air which flows through the discharge region 85.

As a result, the heats of the first and second heat-generating elements 10, 11 and the first and second heat-receiving portions 16, 17 are less liable to stagnate within the housing 2, and a temperature rise within the housing 2 can be prevented.

Further, since the suction ports 79 are covered with the radiator 65 from inside of the housing 2, the running sound of the axial fan 66 can be intercepted by the radiator 65. In addition, since the axial fan 66 lies upstream of the radiator 65 in the flow direction of the cooling air, the cooling air from the axial fan 66 is not blown against the radiator 65.

As a result, whistling at the time when the cooling air passes through the radiator 65 becomes low in level. Therefore, noise developing during the running of the axial fan 66 can be suppressed to a low level, together with the fact that the running sound of the axial fan 66 becomes difficult of leaking through the suction ports 79.

In the first embodiment, the heat exchange type pump 30 and the radiator 65 are respectively provided with the reserve tanks 43, 70 which have the gas-liquid separation function. Therefore, the air bubbles or the like gas components, which permeate through the first through third tubes 91-93 and mix into the liquid coolant, can be separated and removed in the two places of the path through which the liquid coolant is circulated.

In particular, the two reserve tanks 43, 70 are juxtaposed in a serial positional relationship upstream of the pump chamber 42 of the heat exchange type pump 30. Accordingly, the air bubbles hampering the heat transmission can be reliably excluded from the liquid coolant which flows into the pump chamber 42, and the cooling efficiency of the second heat-generating element 11 which becomes the highest temperature can be heightened.

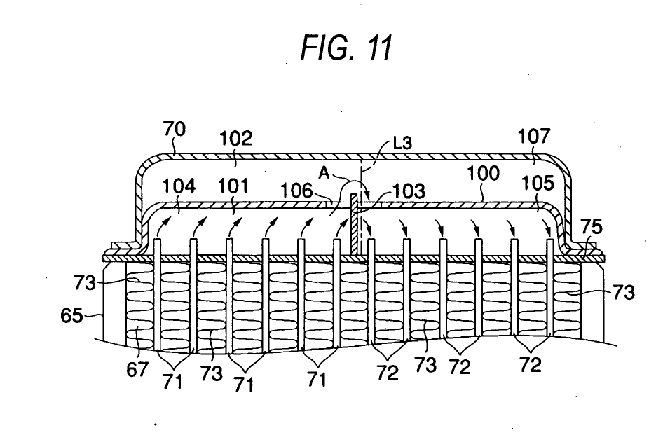

Incidentally, the invention is not specified to the first embodiment described above. FIG. 11 shows the second embodiment of the invention.

The second embodiment differs from the first embodiment in the internal structure of the reserve tank 70 of a radiator 65. The other configuration of the radiator 65 is the same as in the first embodiment.

As shown in FIG. 11, the interior of the reserve tank 70 is partitioned into a first chamber 101 and a second chamber 102 by a baffle plate 100. The baffle plate 100 is brazed to the upper plate 75 of the radiator 65 together with the reserve tank 70.

The upper plate 75 defines the first chamber 101 in cooperation with the baffle plate 100. A partition plate 103 which serves as a gas-liquid separation section is fixed to the upper plate 75. The partition plate 103 partitions the first chamber 101 into a coolant inflow region 104 and a coolant outflow region 105.

The upper ends of the first water pipes 71 of the radiator 65 are open to the coolant inflow region 104. Besides, the upper ends of the first water pipes 71 lie below the liquid level of a liquid coolant stored in the coolant inflow region 104. The upper ends of the second water pipes 72 of the radiator 65 are open to the coolant outflow region 105. Besides, the upper ends of the second water pipes 72 lie below the liquid level of the liquid coolant stored in the coolant outflow region 105.

The baffle plate 100 has an opening 106 at a position corresponding to the partition plate 103. The upper end of the partition plate 103 penetrates through the opening 106, and slightly protrudes into the second chamber 102. Therefore, the coolant inflow region 104 of the first chamber 101 communicates with the coolant outflow region 105 through the opening 106 and the second chamber 102.

The liquid coolant which returns from a first heat-receiving portion 16 to the radiator 65, is discharged from an inflow tank 68 into the coolant inflow region 104 of the reserve tank 70 through the first water pipes 71. As indicated by an arrow A in FIG. 11, the liquid coolant in the coolant inflow region 104 enters the opening 106 and overflows the partition plate 103, thereby to flow out into the coolant outflow region 105.

According to such a configuration, when the liquid coolant stored in the coolant inflow region 104 overflows the partition plate 103, air bubbles or the like gas components contained in the liquid coolant are separated from this liquid coolant and are emitted into the second chamber 102. Therefore, the second chamber 102 of the radiator 65 functions as an air pocket 107.

In a case where the radiator 65 is disposed at a horizontal attitude at which the first and second water pipes 71, 72 become horizontal, the attitude of the radiator 65 is stipulated so that the second water pipes 72 may underlie the first water pipes 71. Thus, as indicated by a two-dot chain line in FIG. 11, the end parts of the second water pipes 72 lie below the liquid level L3 of the liquid coolant within the reserve tank 70, and the partition plate 103 lies above the liquid level L3.

Therefore, the liquid coolant which is discharged from the first water pipes 71 into the coolant inflow region 104 flows from the opening 106 into the coolant outflow region 105 via the second chamber 102 with the partition plate 103 being a guide.

Accordingly, irrespective of whether the radiator 65 is the vertical one or the horizontal one, the gas components hampering heat transmission can be reliably excluded from within the liquid coolant which returns to the reserve tank 70, and the cooling efficiency of a second heat-generating element 11 which becomes the highest temperature can be heightened.

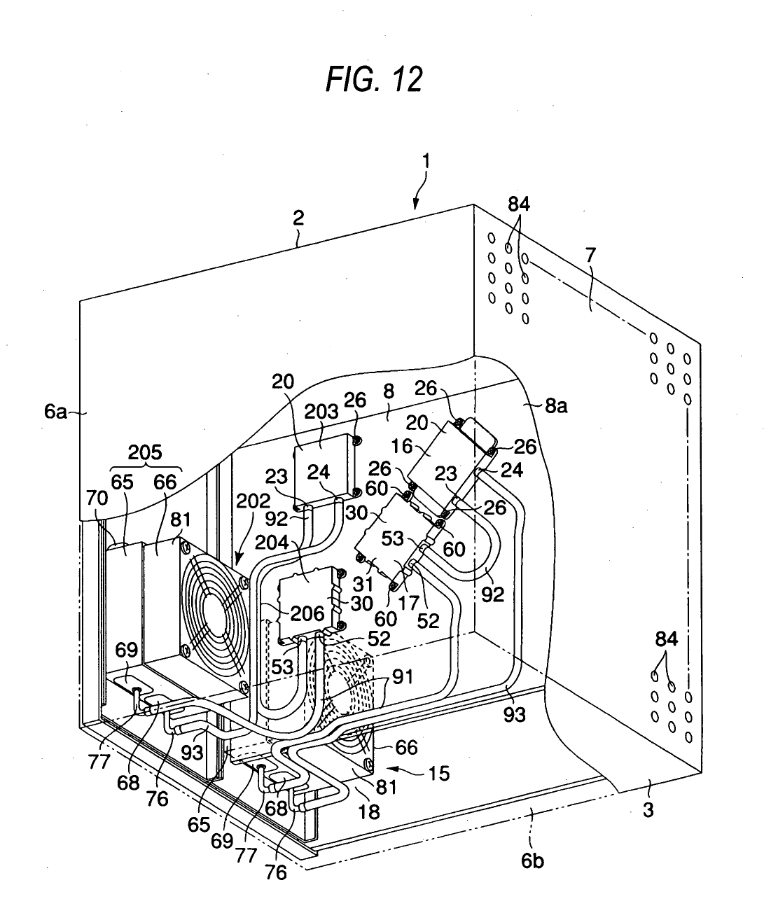

FIGS. 12 through 14 show the third embodiment of the invention.

In the third embodiment, a third heat-generating element 200, and a fourth heat-generating element 201 which is larger than the third heat-generating element 200 in the quantity of heat generation are mounted on the first surface 8a of a printed circuit board 8. Further, a housing 2 accommodates therein another cooling device 202 of liquid cooling scheme as cools the third and fourth heat-generating elements 200, 201.

The third and fourth heat-generating elements 200, 201 are electronic components, for example, semiconductor packages, and they lie ahead of first and second heat-generating elements 10, 11. The fourth heat-generating element 201 which is larger than the third heat-generating element 200 in the quantity of heat generation lies below this third heat-generating element 200.

The other cooling device 202 includes a first heat-receiving portion 203, a second heat-receiving portion 204, a heat radiating unit 205 and a circulation path 206. The first heat-receiving portion 203, second heat-receiving portion 204, heat radiating unit 205 and circulation path 206 correspond to the first heat-receiving portion 16, second heat-receiving portion 17, heat radiating unit 18 and circulation path 19 in the first embodiment, respectively, and their configurations are basically the same as in the first embodiment.

Accordingly, the constituents of each of the first heat-receiving portion 203, second heat-receiving portion 204, heat radiating unit 205 and circulation path 206 are assigned the same reference numerals as in the first embodiment, and they shall be omitted from description.

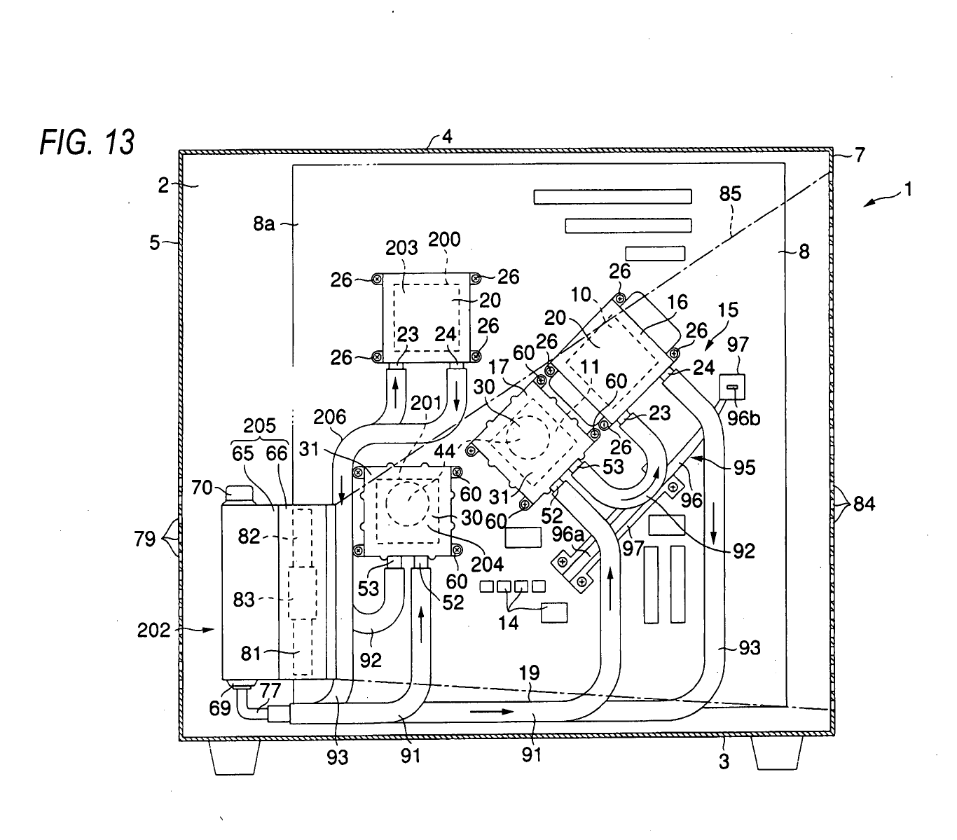

As shown in FIG. 13, the first heat-receiving portion 203 is held on the printed circuit board 8 so as to cover the third heat-generating element 200, and it is thermally connected to the third heat-generating element 200. Likewise, the second heat-receiving portion 204 in which a heat exchange type pump 30 is built is held on the printed circuit board 8 so as to cover the fourth heat-generating element 201, and it is thermally connected to the fourth heat-genrating element 201.

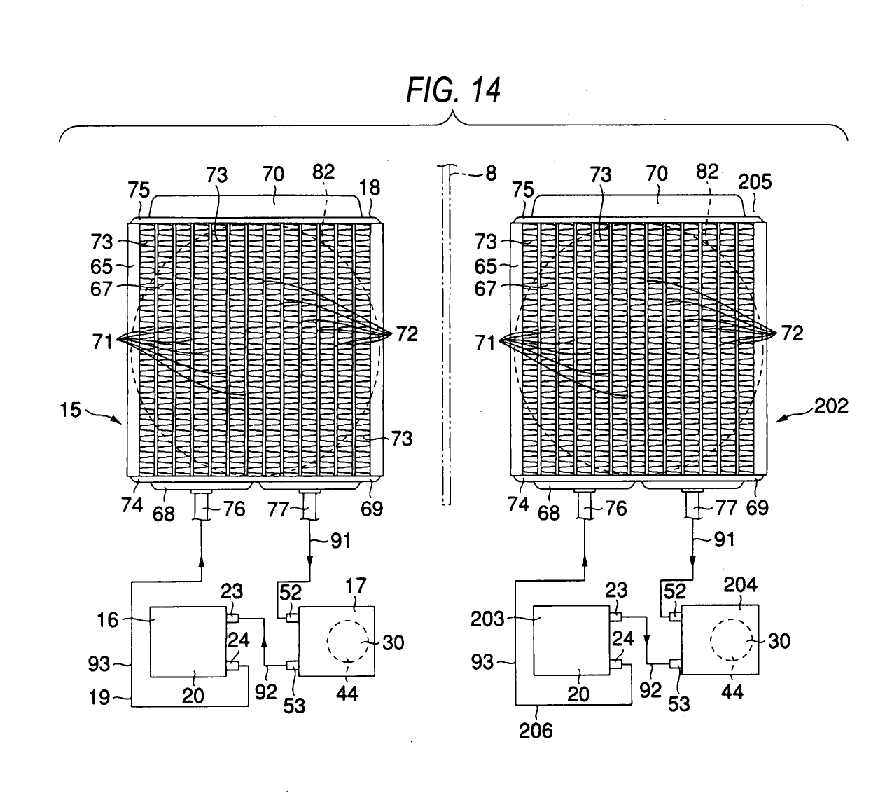

The heat radiating unit 205 is arranged at the lower part of the front end of the housing 2. As shown in FIG. 14, in the third embodiment, the two heat-radiating units 18, 205 are juxtaposed in the width direction of the housing 2, and the front end part of the printed circuit board 8 enters between these heat-radiating units 18, 205.

As shown in FIG. 13, also in the heat radiating unit 205, a radiator 65 confronts a plurality of suction ports 79 which are provided in the front wall 5 of the housing 2, and it covers the suction ports 79 from inside of the housing 2. Further, an axial fan 66 is disposed behind the radiator 65, and it lies on the inner side of the housing 2 with respect to the radiator 65. Therefore, the radiator 65 of the heat radiating unit 205 is located between the suction ports 79 and the axial fan 66.

A liquid coolant cooled by the radiator 65 of the heat radiating unit 205 is first led to the heat exchange type pump 30 of the second heat-receiving portion 204 so as to absorb the heat of the fourth heat-generating element 201 here, and it is thereafter led to the first heat-receiving portion 203. The liquid coolant led to the first heat-receiving portion 203 absorbs the heat of the third heat-generating element 200, and it is thereafter returned to the radiator 65 and is cooled here by heat exchange with cooling air.

As shown in FIG. 13, the second heat-receiving portion 204 which is thermally connected to the fourth heat-generating element 201 larger in the quantity of heat generation is located behind the axial fan 66. Therefore, the second heat-receiving portion 204 lies in a discharge region 85 within the housing 2, and it is directly exposed to cooling air which flows through the discharge region 85.

According to the third embodiment, a temperature rise within the housing 2 can be prevented with the cooling efficiencies of the radiators 65 of the two heat-radiating units 18, 205 heightened. In addition, the running sounds of the axial fans 66 become difficult of leaking through the suction ports 79, and noises attendant upon the runnings of the axial fans 66 can be suppressed to low levels.

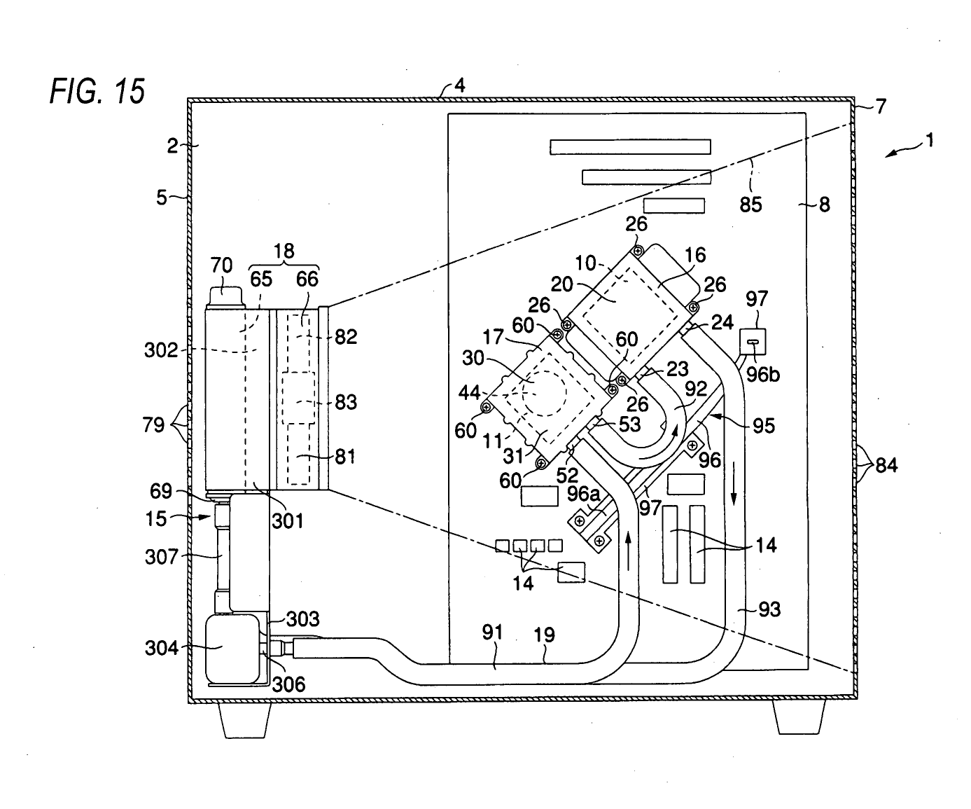

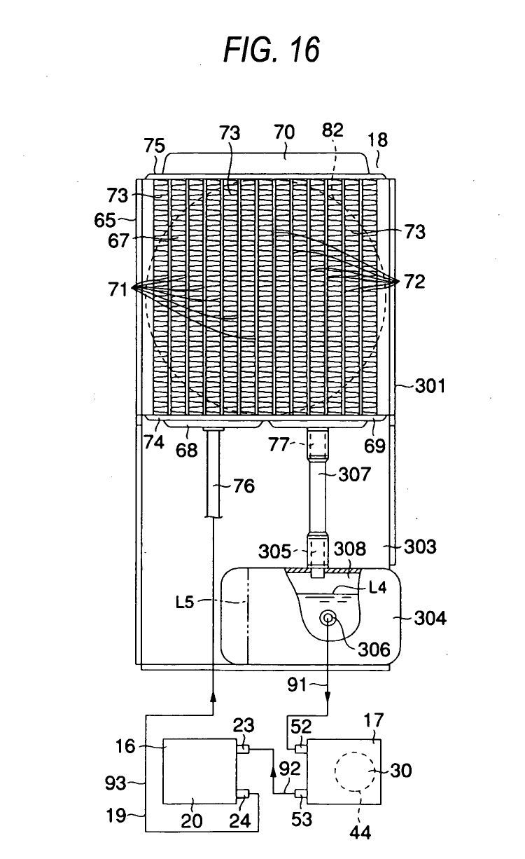

FIGS. 15 and 16 show the fourth embodiment of the invention.

The fourth embodiment differs from the first embodiment in the configuration of the heat radiating unit 18 of a cooling device 15. The other configuration of the cooling device 15 is basically the same as in the first embodiment. In the fourth embodiment, therefore, the same configurational portions as in the first embodiment are assigned the same reference numerals and shall be omitted from description.

As shown in FIGS. 15 and 16, the heat radiating unit 18 includes a frame 301 which integrally couples a radiator 65 and an axial fan 66. The radiator 65 and the axial fan 66 confront each other in spaced fashion. A clearance 302 which appears between the radiator 65 and the axial fan 66, is surrounded with the frame 301.

The frame 301 includes a tank support portion 303 which protrudes toward the underside of the radiator 65. The tank support portion 303 supports a dedicated reserve tank 304. The reserve tank 304 is in the shape of a laterally long box which has a capacity being much larger than that of a reserve tank 70 belonging to the radiator 65, and it lies just under the radiator 65.

In the fourth embodiment, therefore, the radiator 65 and the axial fan 66 are located at an intermediate part along the height direction of a housing 2, and a space for disposing the reserve tank 304 is ensured under the radiator 65.

Further, first and second heat-receiving portions 16, 17 lie behind the axial fan 66. Therefore, the first and second heat-receiving portions 16, 17 lie at substantially the middle part of a discharge region 85 which is defined within the housing 2.

As shown in FIG. 16, the reserve tank 304 includes a coolant inflow port 305 and a coolant outflow port 306. The coolant inflow port 305 is provided at substantially the middle part of the upper surface of the reserve tank 304. This coolant inflow port 305 is connected to the coolant outlet 77 of the radiator 65 through a connection tube 307, and it lies above the liquid level L4 of a liquid coolant stored in the reserve tank 304.

The coolant outflow port 306 is provided at substantially the middle part of the side surface of the reserve tank 304 so as to lie below the coolant inflow port 305. The coolant outflow port 306 is connected to the suction port 52 of a heat exchange type pump 30 through a first tube 91.

The coolant outflow port 306 lies below the liquid level L4 of the liquid coolant within the reserve tank 304. Therefore, an air pocket 308 is formed between the upper surface of the reserve tank 304 and the liquid level L4 of the liquid coolant.

According to such a configuration, the liquid coolant cooled by the radiator 65 flows into the reserve tank 304 through the coolant inflow port 305, upstream of the heat exchange type pump 30 along the flow direction of the liquid coolant. The coolant outflow port 306 of the reserve tank 304 lies below the liquid level L4 of the liquid coolant stored in the reserve tank 304.

Therefore, even when gas components having failed to be separated in the reserve tank 70 of the radiator 65 are contained in the liquid coolant, the gas components are separated and removed from the liquid coolant and are emitted into the air pocket 308 in a process in which the liquid coolant flows into the reserve tank 304.

Accordingly, the reserve tank 304 in this embodiment serves also as a gas-liquid separation section which separates the gas components from the liquid coolant which flows from the radiator 65 toward the heat exchange type pump 30.

According to the fourth embodiment, the three reserve tanks 70, 304, 43 each having the gas-liquid separation function are serially interposed in the flow path of the liquid coolant as leads from the radiator 65 to the pump chamber 42 of the heat exchange type pump 30. Therefore, the gas components hampering heat transmission can be reliably excluded from the liquid coolant which receives the heat of a second heat-generating element 11 in the pump chamber 42, and the cooling efficiency of the second heat-generating element 11 which becomes the highest temperature can be heightened.

Even in a case where the radiator 65 is disposed at a horizontal attitude, the coolant outflow port 306 of the reserve tank 304 lies below the coolant inflow port 305 and the liquid level L5 of the liquid coolant as is indicated by a two-dot chain line in FIG. 14. Accordingly, gas components contained in the liquid coolant are separated and removed from the liquid coolant in a process in which the liquid coolant flows into the reserve tank 304.

Irrespective of whether the radiator 65 is the vertical one or the horizontal one, the gas components hampering heat transmission can be reliably excluded from the liquid coolant.

According to the fourth embodiment, the clearance 302 is formed between the radiator 65 and the axial fan 66, and hence, this axial fan 66 comes to suck air in the clearance 302. Therefore, as compared with those in the case where the radiator 65 and the axial fan 66 are held in close contact, a suction resistance during the operation of the axial fan 66 can be suppressed to a lower value, and whistling from the radiator 65 becomes more difficult to arise.

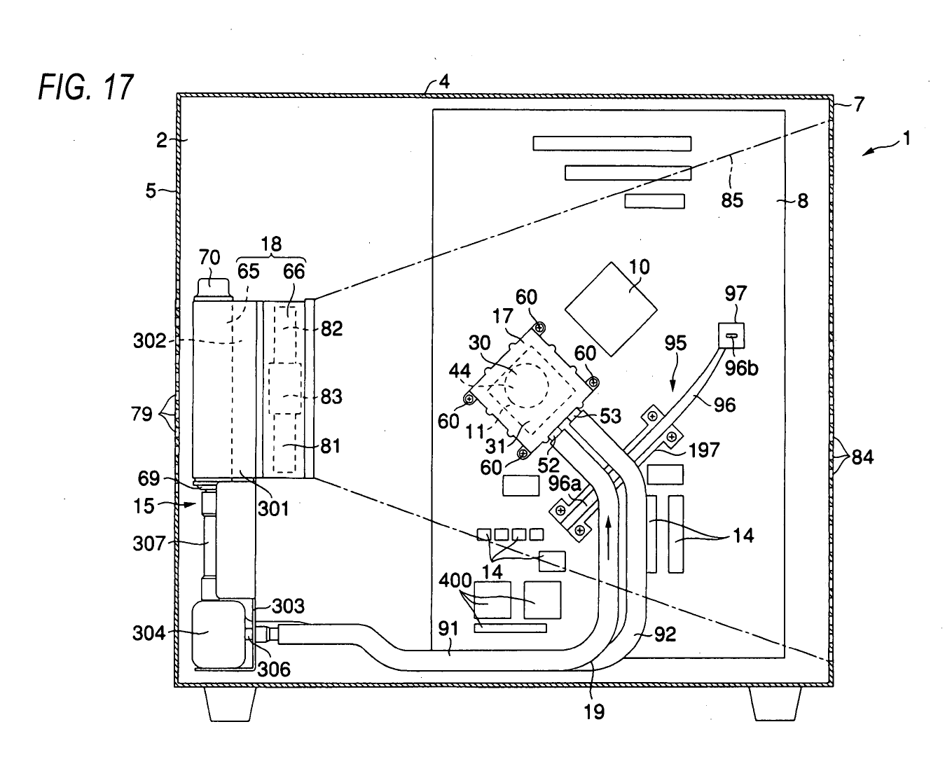

FIG. 17 shows the fifth embodiment of the invention.

The fifth embodiment differs from the fourth embodiment in the point that only a second heat-generating element 11 which is larger than a first heat-generating element 10 in the quantity of heat generation is forcibly cooled through a liquid coolant. The other configuration of a computer 1 is basically the same as in the fourth embodiment. In the fifth embodiment, therefore, the same configurational portions as in the fourth embodiment are assigned the same reference numerals and shall be omitted from description.

As shown in FIG. 17, a second heat-receiving portion 17 is thermally connected to the second heat-generating element 11. The discharge port 53 of the second heat-receiving portion 17 is connected to the coolant inlet 76 of a radiator 65 through a second tube 92.

In the fifth embodiment, the first heat-generating element 10 which is smaller than the second heat-generating element 11 in the quantity of heat generation lies in a discharge region 85 which extends from an axial fan 66 to exhaust ports 84. Therefore, the first heat-generating element 10 is forcibly cooled by cooling air which flows through the discharge region 85.

A plurality of electronic components 400 which generate heats are mounted on the first surface 8a of a printed circuit board 8. The electronic components 400 lie outside the discharge region 85 through which the cooling air flows, and they lie in the vicinity of the heat receiving end part 96a of a heat pipe 96.

When the electronic components 400 generate the heats, their heats are transmitted to the heat pipe 96 via the printed circuit board 8. As a result, the heats of the electronic components 400 are transferred to heat radiating fins 97 by the heat transfer action of the heat pipe 96, and they are radiated while being carried on the streams of the cooling air which flows through the discharge region 85 from the surfaces of the heat radiating fins 97.

The heats of the electronic components 400 lying outside the discharge region 85 can be transferred into the discharge region 85 and be positively radiated therefrom. Consequently, the heats of the circuit components 400 are less liable to stagnate within a housing 2, and the rise of the internal temperature of the housing 2 can be prevented.

The invention is not specified to the foregoing embodiments, but it can be variously altered and performed within a scope not departing from the purport thereof.

In each embodiment, the heat exchange type pump is integrally assembled in the heat receiving portion which receives the heat of the heat generating element. However, the invention is not restricted to this aspect, but the pump for pressurizing the liquid coolant, and the heat receiving portion may well be detached from each other.

While certain embodiments of the inventions have been described, the embodiments have been presented by example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing including a suction port and an exhaust port;
a heat generating element accommodated in the housing;
a heat receiving portion accommodated in the housing, and thermally connected to the heat generating element;
a fan disposed in the vicinity of the suction port within the housing, and which sucks a cooling air through the suction port; and
a heat radiating portion accommodated in the housing, and configured to radiate heat of the heat generating element;
wherein the heat radiating portion is disposed between the suction port and the fan; and
the heat receiving portion is arranged in a discharge region of the cooling air extending from the fan to the exhaust port.

2. The electronic apparatus as claimed in claim 1,
wherein the heat radiating portion covers the suction port from inside of the housing.

3. The electronic apparatus as claimed in claim 1, further comprising:
a second heat-generating element placed outside the discharge region;
a heat pipe including a heat receiving end part for receiving heat of the second heat-generating element and a heat radiating end part which radiating heat of the second heat-generating element; and
a heat radiating fin thermally connected to the heat radiating end part;
wherein the second heat-generating element, the heat pipe, and the heat radiating fin are accommodated in the housing, and
wherein the heat radiating end part of the heat pipe and the heat radiating fin are placed in the discharge region.

4. The electronic apparatus as claimed in claim 1, further comprising:
a frame that integrally connects the heat radiating portion and the fan,
wherein the heat radiating portion and the fan are separately arranged to define a clearance therebetween.

5. An electronic apparatus comprising:
a housing including a suction port and an exhaust port;
a heat generating element accommodated in the housing;
a heat receiving portion accommodated in the housing, and which receives heat of the heat generating element;
a fan disposed in the vicinity of the suction port within the housing, and which sucks a cooling air through the suction port;
a heat radiating portion accommodated in the housing, and configured to radiate heat of the heat generating element; and
a circulation path which circulates a liquid coolant between the heat receiving portion and the heat radiating portion, and which transfers the heat of the heat receiving portion transmitted from the heat generating element to the heat radiating portion through the liquid coolant;
wherein the heat radiating portion is disposed between the suction port and the fan, and
wherein the heat receiving portion is arranged in a discharge region of the cooling air extending from the fan to the exhaust port.

6. The electronic apparatus as claimed in claim 5, further comprising:
a first reserve tank accommodated in the heat receiving portion; and
a second reserve tank accommodated in the heat radiating portion;
wherein each of the first reserve tank and the second reserve tank stores the liquid coolant and has a gas-liquid separation section that separates gas contained in the liquid coolant.

7. The electronic apparatus as claimed in claim 5, further comprising:
a third reserve tank configured to store the liquid coolant and placed in a leading part of the heat radiating portion which leads the liquid coolant cooled by the heat radiating portion into the heat receiving portion;
wherein the third reserve tank is integrated in the circulation path; and
wherein the third reserve tank has a gas-liquid separation section that separates gas contained in the liquid coolant.

8. The electronic apparatus as claimed in claim 5, wherein the heat receiving portion includes a pump which pressurizes and delivers the liquid coolant.

9. The electronic apparatus as claimed in claim 5, further comprising:
a frame that integrally connects the heat radiating portion and the fan,
wherein the heat radiating portion and the fan are separately arranged to define a clearance therebetween.
